(19) United States
(12) Patent Application Publication
(10) Pub. No.: US 2017/0221584 A1
(43) Pub. Date: Aug. 3, 2017

(54) SSD CONTROLLING CIRCUIT FOR DETERMINING REUSABILITY OF DATA BLOCK OF SSD

(71) Applicant: Realtek Semiconductor Corp., Hsinchu (TW)

(72) Inventors: Yen-Chung CHEN, Hsinchu County (TW); Cheng-Yu CHEN, New Taipei City (TW); Shuang-Xi CHEN, Suzhou (CN)

(73) Assignee: Realtek Semiconductor Corp., Hsinchu (TW)

(21) Appl. No.: 15/389,807

(22) Filed: Dec. 23, 2016

(30) Foreign Application Priority Data
Jan. 29, 2016 (CN) 201610065328.0

(51) Int. Cl. G11C 29/44; G11C 29/36; G11C 29/38; G06F 3/06

(52) U.S. Cl. CPC G11C 29/4401; G06F 3/0619; G06F 3/064; G06F 3/0679; G11C 29/36; G11C 29/38

(57) ABSTRACT

A SSD controlling circuit includes: a read and write circuit for coupling with a SSD; and a flash memory controlling circuit coupled with the read and write circuit and configured to operably conduct following operations: reading data from a target data block of the SSD and conduct error checking and correction operation on retrieved data; if uncorrectable error occurs, moving data of the target data block to other blocks; erasing the target data block; writing test data into the target data block; after a predetermined time, reading test data from the target data block and conduct error checking and correction operation on retrieved data; recording error counts of the target data block; and determining the reusability of the target data block according to the recorded error counts.

### CROSS-REFERENCE TO RELATED APPLICATIONS

This application claims the benefit of priority to Patent Application No. 201610065328.0, filed in China on Jan. 29, 2016; the entirety of which is incorporated herein by reference for all purposes.

### BACKGROUND

The disclosure generally relates to a solid state drive (SSD) and, more particularly, to a SSD controlling circuit for determining reusability of the data blocks in the SSD.

As is well known in the art, data stored in the SSD may get lost due to read disturb or abnormal aging of the data blocks. In addition, the data may also get lost when the data is idle longer than the data retention period or when the access limit of the data block is reached.

Existing technologies can only rely on the erase counts of a data block to determine whether the data block approaches to its access limit or not, but cannot determine whether data lost is caused by an abnormal aging of the data block or not. If a data block that suffers abnormal aging but not yet reaches the limit of erase counts continues to be used for storing data, then data lost situation may repeatedly occur, thereby severely degrading the reliability of the SSD.

### SUMMARY

An example embodiment of a SSD controlling circuit of a solid state drive device (100 is disclosed. The solid state drive device comprises a SSD and a communication interface. The SSD controlling circuit comprises: a read and write circuit arranged to operably couple with the SSD; and a flash memory controlling circuit, coupled with the read and write circuit, utilized for coupling with the communication interface and arranged to operably perform following operations: (A1) reading data from a first data block of the SSD through the read and write circuit, and conducting an error checking and correction operation on retrieved data; (B1) if uncorrectable error occurs in the data retrieved in the operation (A1), moving data stored in the first data block to other blocks; (C1) erasing the first data block through the read and write circuit; (D1) writing test data into the first data block through the read and write circuit; (E1) waiting for a predetermined period of time and then reading test data from the first data block through the read and write circuit, and conducting an error checking and correction operation on retrieved data; (F1) recording error count of the first data block; and (G1) determining reusability of the first data block according to a recorded error count of the first data block.

Both the foregoing general description and the following detailed description are examples and explanatory only, and are not restrictive of the invention as claimed.

### BRIEF DESCRIPTION OF THE DRAWINGS

FIG. 1 shows a simplified functional block diagram of a SSD device according to one embodiment of the present disclosure.

FIG. 2 shows a simplified flowchart of a method for determining the reusability of the data blocks in a SSD according to one embodiment of the present disclosure.

### DETAILED DESCRIPTION

Reference is made in detail to embodiments of the invention, which are illustrated in the accompanying drawings. The same reference numbers may be used throughout the drawings to refer to the same or like parts, components, or operations.

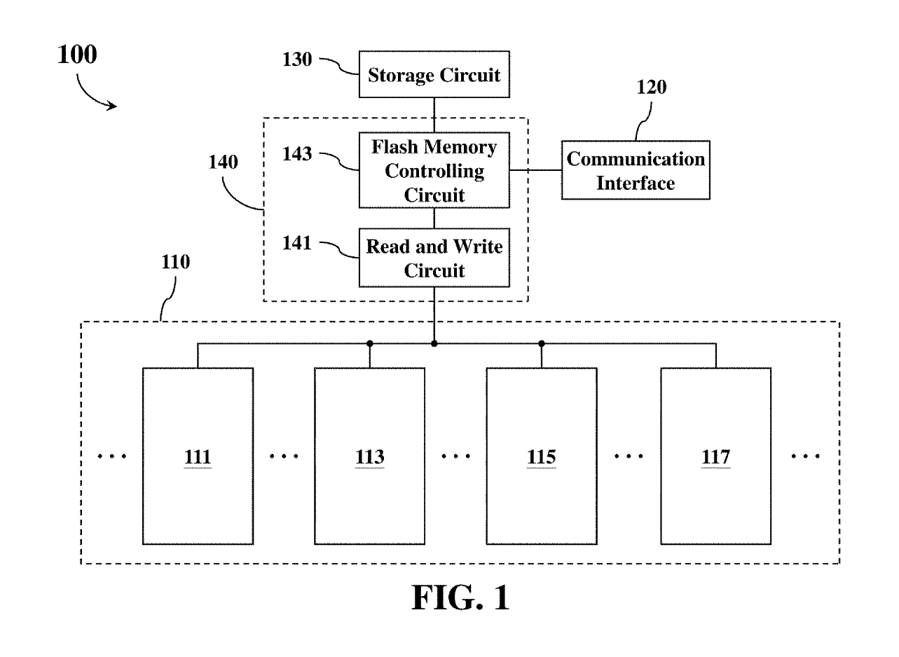

FIG. 1 shows a simplified functional block diagram of a SSD (solid state drive) device 100 according to one embodiment of the present disclosure. The solid state drive device 100 comprises a SSD 110, a communication interface 120, a storage circuit 130, and a SSD controlling circuit 140.

The SSD 110 comprises multiple physical data blocks, such as a first data block 111, a second data block 113, a third data block 115, and a fourth data block 117 shown in FIG. 1. The communication interface 120 is arranged to operably communicate with a host device (not shown). The SSD controlling circuit 140 comprises a read and write circuit 141 and a flash memory controlling circuit 143.

As shown in FIG. 1, the read and write circuit 141 is coupled with the SSD 110. The flash memory controlling circuit 143 is coupled with the read and write circuit 141 and utilized for coupling with the communication interface 120 and the storage circuit 130. The flash memory controlling circuit 143 is arranged to operably control the accessing of the SSD 110.

In practice, the communication interface 120 may be realized with a SATA (Serial Advanced Technology Attachment) interface, a PCIe (peripheral component interconnect express) interface, or a hybrid of the above two interfaces. In addition, the storage circuit 130 may be realized with an independent device outside the SSD controlling circuit 140, or may be integrated into the SSD controlling circuit 140.

For simplicity of illustration, other components in the solid state drive device 100 and their connections, operations, and implementations are not shown in FIG. 1.

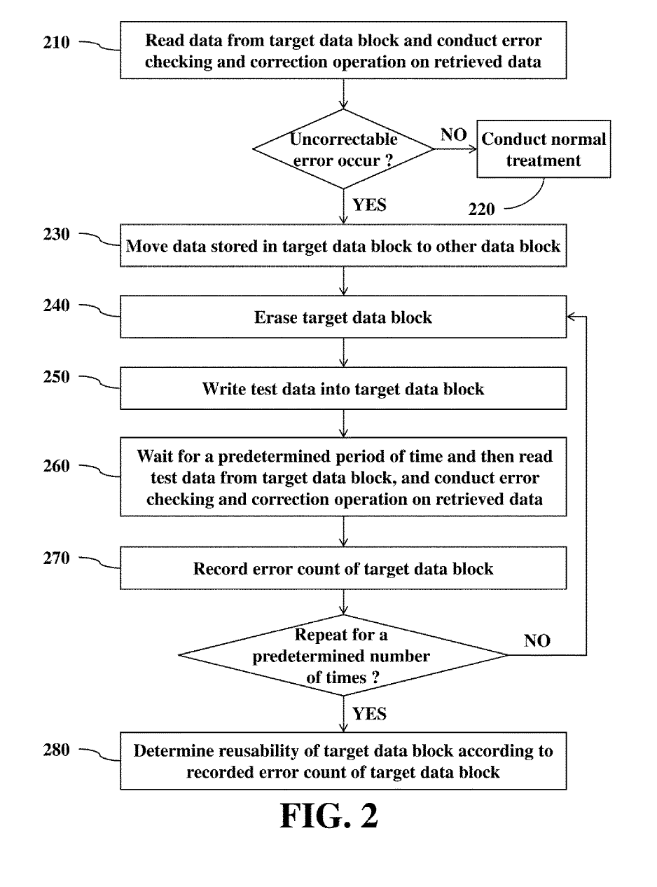

The operations of the solid state drive device 100 will be further described in the following by reference to FIG. 2.

FIG. 2 shows a simplified flowchart of a method for determining the reusability of the data blocks in the SSD 110 according to one embodiment of the present disclosure.

In the operation 210, the flash memory controlling circuit 143 of the SSD controlling circuit 140 may read data from a target data block of the SSD 110 through the read and write circuit 141, and conduct an error checking and correction operation on retrieved data.

In practice, the flash memory controlling circuit 143 may perform the operation 210 when received a read command from the host device through the communication interface 120, or may actively perform the operation 210 during an idle time at which the host device does not need to access the SSD 110. Accordingly, the aforementioned target data block may be a data block indicated by the host device or a data block selected by the flash memory controlling circuit 143 for testing.

For illustrative purpose, it is assumed hereafter that the aforementioned target data block is the first data block 111.

If the data retrieved from the first data block 111 has no error, the flash memory controlling circuit 143 proceeds to the operation 220. If some errors occur in the data retrieved from the first data block 111 but those errors are correctable, the flash memory controlling circuit 143 also proceeds to the operation 220.

On the contrary, if uncorrectable error occurs in the data retrieved from the first data block 111, the flash memory controlling circuit 143 performs the operation 230 and subsequent block testing operations to determine whether the first data block 111 has abnormal problem or not.

In the operation 220, the flash memory controlling circuit 143 conducts normal treatment to the retrieved data. For example, if the operation 210 was performed by the flash memory controlling circuit 143 when a read command transmitted from the host device is received by the flash memory controlling circuit 143, the flash memory controlling circuit 143 may transmit the retrieved data to the host device through the communication interface 120 in the operation 220. If the flash memory controlling circuit 143 was performing the operation 210 in an idle period, the flash memory controlling circuit 143 may conduct no treatment to the retrieved data at all in the operation 220.

In the operation 230, the flash memory controlling circuit 143 may move the data stored in the first data block 111 to another data block, such as the fourth data block 117.

In the operation 240, the flash memory controlling circuit 143 may erase the first data block 111 through the read and write circuit 141.

In the operation 250, the flash memory controlling circuit 143 may write test data into the first data block 111 through the read and write circuit 141. For example, the flash memory controlling circuit 143 may write test data into all physical pages of the first data block 111 using a first writing scheme. The flash memory controlling circuit 143 may configure the aforementioned first writing scheme to be identical to the writing scheme of the data retrieved by the flash memory controlling circuit 143 in the operation 210, so as to reduce variable in the block testing operation to thereby increase the testing accuracy of the data block.

For example, supposing that general data blocks have three writing schemes, one-bit-per-cell (1 bpc) scheme, two-bit-per-cell (2 bpc) scheme, and three-bit-per-cell (3 bpc) scheme.

In this situation, if the original writing scheme of the data stored in the first data block 111 is the 1 bpc scheme when the flash memory controlling circuit 143 performs the operation 210, the flash memory controlling circuit 143 would write test data into the first data block 111 using the 1 bpc scheme in the operation 250. If the original writing scheme of the data stored in the first data block 111 is the 3 bpc scheme when the flash memory controlling circuit 143 performs the operation 210, the flash memory controlling circuit 143 would write test data into the first data block 111 using the 3 bpc scheme in the operation 250.

In the operation 260, the flash memory controlling circuit 143 would wait for a predetermined period of time and then read test data from the first data block 111 through the read and write circuit 141, and then conduct an error checking and correction operation on the retrieved data.

It may be difficult to detect whether abnormal aging occurs in the data block if the operation 260 is performed immediately after the operation 250. Therefore, according to one embodiment, the flash memory controlling circuit 143 may configure the predetermined period of time in the operation 260 to be at least one minute, so as to increase the testing accuracy of the data block. In addition, the predetermined period of time may be dynamically adjusted by the flash memory controlling circuit 143 based on the operating temperature or the erase count of the first data block 111, instead of a fixed value.

In the operation 270, the flash memory controlling circuit 143 may record the error count of the first data block 111 in the storage circuit 130.

In the operation 280, the flash memory controlling circuit 143 may determine the reusability of the first data block 111 according to the recorded error count of the first data block 111.

For example, if the error count of the first data block 111 exceeds a predetermined threshold, it means that the hardware condition of the first data block 111 does not satisfy a required standard, and the flash memory controlling circuit 143 may thus determine that the first data block 111 is an abnormal data block that does not reach the erase count limit but suffers abnormal aging. Accordingly, the flash memory controlling circuit 143 determines that the first data block 111 no longer has reusability, and marks the first data block 111 as an abnormal data block not suitable for storing data any more.

In practice, the flash memory controlling circuit 143 may repeat the operations 240 through 270 for a predetermined number of times before performing the operation 280 to reduce the possibility of erroneously marking the first data block 111 as an abnormal data block. For example, in order to increase the testing accuracy of the data block but not to increase the erase count of the data block too much, the flash memory controlling circuit 143 may repeat the operations 240 through 270 for three times before performing the operation 280. In addition, the aforementioned predetermined number of times may be flexibly modified by the flash memory controlling circuit 143 when the SSD 110 approaches to an EOL (end-of-life) condition. For example, the aforementioned predetermined number of times may be modified in light of the erase count of the first data block 111 to prevent over test the data block.

The determination criterion adopted by the flash memory controlling circuit 143 in the operation 280 may be configured based on the actual application environment. In one embodiment, for example, as long as an uncorrectable error occurs in the first data block 111 in any test period, the flash memory controlling circuit 143 determines that the first data block 111 no longer has reusability.

In another embodiment, the flash memory controlling circuit 143 determines that the first data block 111 no longer has reusability if the first data block 111 is found to have uncorrectable errors in more than half test periods.

In another embodiment, the flash memory controlling circuit 143 determines that the first data block 111 no longer has reusability if the first data block 111 is found to have uncorrectable errors in all test periods.

As describe previously, the flash memory controlling circuit 143 may configure the writing scheme used for writing the test data in the operation 250 to be identical to the original writing scheme that was used to write the data retrieved in the operation 210. Accordingly, the SSD controlling circuit 140 may utilize different writing schemes when testing the reusability of different data blocks.

For example, assuming that the flash memory controlling circuit 143 again performs the reusability testing operations of FIG. 2 on the second data block 113 after finishing the reusability testing operations on the first data block 111. In this situation, the flash memory controlling circuit 143 may write test data into all physical pages of the second data block 113 using a second writing scheme, and configure the second writing scheme to be identical to the original wiring scheme of the data retrieved from the second data block 113 in the operation 210. If the original writing scheme of the data stored in the second data block 113 when the flash memory controlling circuit 143 performs the operation 210 on the second data block 113 is the 2 bpc scheme, the flash memory controlling circuit 143 would also write the test data into the second data block 113 using the 2 bpc scheme in the operation 250.

In the previous embodiment, the flash memory controlling circuit 143 writes the test data into the first data block 111 using the 1 bpc scheme or the 3 bpc scheme. Accordingly, the writing scheme utilized by the SSD controlling circuit 140 in testing the reusability of the second data block 113 (i.e., the 2 bpc scheme in this case) is apparently different from the writing scheme utilized by the SSD controlling circuit 140 in testing the reusability of the first data block 111 (i.e., the 1 bpc scheme or the 3 bpc scheme). Such approach can reduce the variable during the data block testing operation, thereby increasing the testing accuracy of the data blocks.

The foregoing descriptions regarding the operations and related advantages of other corresponding steps conducted by the SSD controlling circuit 140 in testing the reusability of the first data block 111 are also applicable to the testing operations of the second data block 113. For the sake of brevity, those descriptions will not be repeated here.

It can be appreciated from the foregoing descriptions that as long as the flash memory controlling circuit 143 determines that a specific data block no longer has reusability, it means that the specific data block is highly likely a data block suffering abnormal aging problem due to various causes. Thus, the flash memory controlling circuit 143 marks the specific data block as an abnormal data block not suitable for storing data any more, in order to prevent the abnormal data block from being used for storing data.

As a result, data lost problems caused by abnormal aging of the data blocks can be effectively avoided.

Other embodiments of the invention will be apparent to those skilled in the art from consideration of the specification and practice of the invention disclosed herein. It is intended that the specification and examples be considered as exemplary only, with a true scope and spirit of the invention indicated by the following claims.

What is claimed is:

1. A SSD controlling circuit (140) of a solid state drive device (100), wherein the solid state drive device (100) comprises a SSD (110) and a communication interface (120), the SSD controlling circuit (140) comprising:
a read and write circuit (141) arranged to operably couple with the SSD (110); and
a flash memory controlling circuit (143), coupled with the read and write circuit (141), utilized for coupling with the communication interface (120) and arranged to operably perform following operations:
(A1) reading data from a first data block (111) of the SSD (110) through the read and write circuit (141), and conducting an error checking and correction operation on retrieved data;
(B1) if uncorrectable error occurs in the data retrieved in the operation (A1), moving data stored in the first data block (111) to other blocks;
(C1) erasing the first data block (111) through the read and write circuit (141);
(D1) writing test data into the first data block (111) through the read and write circuit (141);
(E1) waiting for a predetermined period of time and then reading test data from the first data block (111) through the read and write circuit (141), and conducting an error checking and correction operation on retrieved data;
(F1) recording error count of the first data block (111); and
(G1) determining reusability of the first data block (111) according to a recorded error count of the first data block (111).

2. The SSD controlling circuit (140) of claim 1, wherein the flash memory controlling circuit (143) at least repeats the operations (C1)˜(F1) for a predetermined number of times before performing the operation (G1).

3. The SSD controlling circuit (140) of claim 2, wherein the predetermined number is three.

4. The SSD controlling circuit (140) of claim 2, wherein the predetermined number is determined based on an erase count of the first data block (111).

5. The SSD controlling circuit (140) of claim 1, wherein the flash memory controlling circuit (143) writes the test data into the first data block (111) using a first writing scheme through the read and write circuit (141) in the operation (D1), and the first writing scheme is identical to a writing scheme of the data retrieved from the first data block (111) in the operation (A1).

6. The SSD controlling circuit (140) of claim 5, wherein the flash memory controlling circuit (143) is further arranged to operably perform following operations:
(A2) reading data from a second data block (113) of the SSD (110) through the read and write circuit (141), and conducting an error checking and correction operation on retrieved data;
(B2) if uncorrectable error occurs in the data retrieved in the operation (A2), moving data stored in the second data block (113) to other blocks;
(C2) erasing the second data block (113) through the read and write circuit (141);
(D2) writing test data into the second data block (113) using a second writing scheme through the read and write circuit (141);
(E2) waiting for the predetermined period of time and then reading test data from the second data block (113) through the read and write circuit (141), and conducting an error checking and correction operation on retrieved data;
(F2) recording error count of the second data block (113); and
(G2) determining reusability of the second data block (113) according to a recorded error count of the second data block (113);
wherein the second writing scheme is identical to a writing scheme of the data retrieved from the second data block (113) in the operation (A2), but different from the first writing scheme.

7. The SSD controlling circuit (140) of claim 1, wherein a length of the predetermined period of time in the operation (E1) is at least one minute.

8. The SSD controlling circuit (140) of claim 1, wherein a length of the predetermined period of time in the operation (E1) is dynamically configured based on temperature or an erase count of the first data block (111).
